(19) United States
(12) Patent Application Publication
(10) Pub. No.: US 2013/0069724 A1
(43) Pub. Date: Mar. 21, 2013

(54) SUPPLY INDEPENDENT BIASING CIRCUIT

(71) Applicant: Yuwen Swei, Fremont, CA (US)

(72) Inventor: Yuwen Swei, Fremont, CA (US)

(73) Assignee: TAIWAN SEMICONDUCTOR MANUFACTURING CO., LTD., Hsin-Chu (TW)

(21) Appl. No.: 13/237,177

(22) Filed: Sep. 20, 2011

(51) Int. Cl. H03F 3/45

(52) U.S. Cl. 330/257

(57) ABSTRACT

A supply-independent biasing source includes an upper current mirror including first and second PMOS transistors and a lower current mirror coupled to the upper current mirror including first and second NMOS transistors. The first NMOS and first PMOS transistors have drain terminals coupled together and form a first stack of transistors and the second NMOS and second PMOS transistors have drain terminals coupled together and form a second stack of transistors. A first resistive load is connected to one of the first and second stacks, wherein the resistive load comprises a first MOSFET transistor biased at triode region.

### TECHNICAL FIELD

This disclosure relates to supply independent biasing circuits.

### BACKGROUND

Supply-independent biasing circuits, i.e., biasing circuits that provide DC levels with little dependence on supply levels, are widely used in analog systems such as differential amplifiers and other circuits that require constant current or voltage levels. These supply-independent circuits are still dependent on component process parameters and temperature variations. To avoid such variation, a bandgap reference and voltage-to-current combination must be used, which increases the complexity of the design, power consumption and area.

### BRIEF DESCRIPTION OF THE DRAWINGS

FIG. 1 illustrates an embodiment of a supply-independent biasing circuit.

FIG. 2 illustrates an alternative embodiment of the supply-independent biasing circuit of FIG. 1 where the on-die resistance is replaced with a MOSFET biased in the triode region.

FIG. 3A illustrates an embodiment of another supply-independent biasing circuit, and FIG. 3B illustrates an alternative embodiment of the supply-independent biasing circuit of FIG. 3A where the on-die resistance is replaced with a MOSFET biased in the triode region.

FIG. 4A illustrates an embodiment of another supply-independent biasing circuit, and FIG. 4B illustrates an alternative embodiment of the supply-independent biasing circuit of FIG. 4A where the on-die resistance is replaced with a MOSFET biased in the triode region.

FIG. 4C illustrates an alternative embodiment of the supply-independent biasing circuit of FIG. 4B.

FIG. 5 illustrates a method of supply-independent biasing.

### DETAILED DESCRIPTION

This description of the exemplary embodiments is intended to be read in connection with the accompanying drawings, which are to be considered part of the entire written description. In the description, terms concerning coupling and the like, such as “coupled”, “connected” and “interconnected,” refer to a relationship wherein structures communicate with one another either directly or indirectly through intervening structures unless expressly described otherwise.

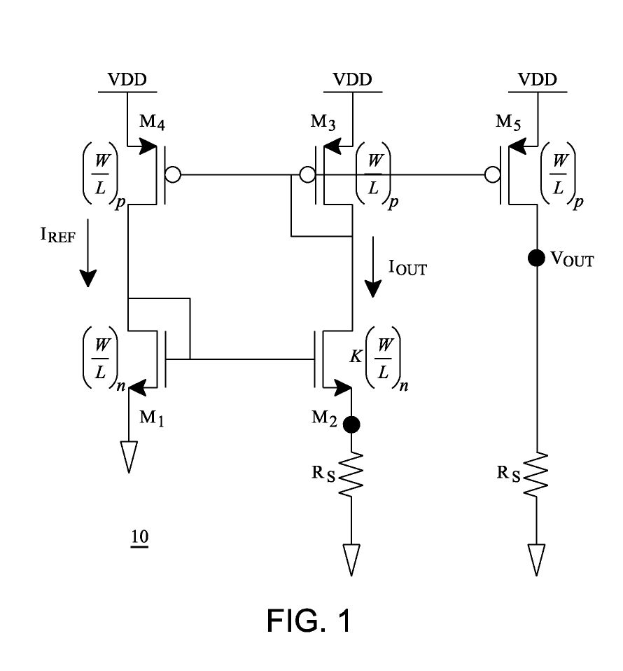

FIG. 1 illustrates an embodiment of a supply-independent biasing circuit 10, specifically for providing a supply-independent current I_{OUT} and supply-independent voltage V_{OUT} therefrom. The biasing circuit 10 is self biasing by using current mirroring to derive the reference current I_{REF} from the output current I_{OUT} and vice versa. The biasing circuit 10 includes two current mirrors, an upper current mirror including transistors M3 and M4, with the gate and drain terminals of M4 connected together (i.e., a diode connection), and a lower current mirror including transistors M1 and M2, with the gate and drain terminals of M1 connected together. PMOS transistors M3 and M4 copy I_{OUT}, thereby defining I_{REF}. Basically, I_{REF} is bootstrapped to I_{OUT}. Because each diode-connected device (i.e., M₃ and M₁) feeds from a current source, I_{REF} and I_{OUT} are relatively independent of VDD. Therefore, the magnitude of I_{REF} and I_{OUT} is set by other parameters. Resistor R_{S} can be used to further uniquely define the currents. Specifically, resistor R_{S} decreases the current of M2 while the PMOS devices M3, M4 ensure that I_{OUT} is equal to I_{REF}, because the PMOS devices M3, M4 have the same dimensions (W/L)ₚ.

Transistor M5 forms a third current mirror with PMOS M3 and is designed to have the same physical dimensions and biasing as transistors M3 and M4. As a consequence, when the gate voltage of M3 and M4 is applied to the gate of M5, the output current of M5 also becomes equal to I_{REF} and I_{OUT}. This current can be used to generate a supply independent output voltage V_{OUT}, which is equal to I_{OUT}×R_{S}.

If M1 to M4 operate in saturation mode and the channel-length modulation parameter λ is assumed ignored (i.e., it is assumed that the transistor length is large), then the current I_{OUT} simply equals K×I_{REF}, where K is the size ratio between NMOS transistors M2 and M1. As should be apparent from the formula presented below, current will flow as long as K is not equal to 1. K is usually an integer, e.g. 8, 16 or even larger. For this circuit, I_{OUT} and V_{OUT} conform to the following equations:

$${I}_{OUT} = \frac{2}{{μ}_{n} {{C}_{ox} ( W \text{/} L )}_{n}} \frac{1}{{R}_{S}^{2}} {( 1 - \frac{1}{\sqrt{K}} )}^{2}$$

$${V}_{OUT} = {I}_{OUT} {R}_{S} = \frac{2}{{μ}_{n} {{C}_{ox} ( W \text{/} L )}_{n}} \frac{1}{{R}_{S}} {( 1 - \frac{1}{\sqrt{K}} )}^{2}$$

where μₙ is the charge-carrier effective mobility, W is the gate width, L is the gate length and Cₒₓ is the gate oxide capacitance per unit area.

The on-die resistance can be provided by a polysilicon resistors or diffusion resistor. The current I_{OUT} is relatively insensitive to small fluctuations in supply voltage VDD but is still dependent on the on-die resistance R_{S}, which can vary significantly with process variations. Specifically, the current I_{OUT} varies proportional to the reciprocal of the square of the resistance of R_{S}. By way of example, if the on-die resistance can vary by +/−30%, then the current can easily vary from −50% to +70% from the target.

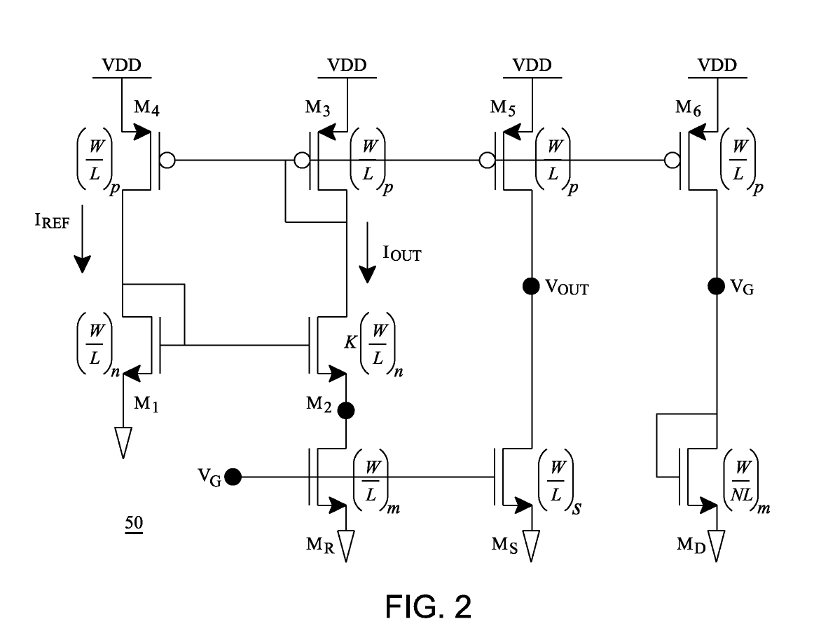

FIG. 2 illustrates an alternative embodiment of the biasing circuit of FIG. 1 where the supply-independent bias current is not sensitive to on-die resistance variations. Specifically, in biasing circuit 50 the resistors R_{S} are replaced with NMOS transistor M_{R} and M_{S}, which is biased at the triode region. In this embodiment, both I_{OUT} and V_{OUT} are independent of the resistance value and supply voltage VDD. That is, as long as the value of V_{G}−Vₜₕₙ of M_{R} and M_{S} is much greater than V_{DS} of M_{R} and M_{S}, then the I_{OUT} and V_{OUT} depend only on the transistor ratio. Transistors M_{R} and M_{S} can be sized the same or differently. If M₁ and M₂ are sized properly, then both I_{OUT} and V_{OUT} are no longer dependent on the on-die resistor process variations from. This is shown by the equations below.

First, assume that the transistor size of M_{R} and M_{S} are the same and biased in triode region. The value of these resistances R_{MR} and R_{MS} then conforms to the following equation:

$${R}_{MR} = {R}_{MS} = \frac{1}{{μ}_{n} {{C}_{ox} ( W \text{/} L )}_{m} ( {V}_{G} - {V}_{thn} )}$$

Using the I_{OUT} formula from above, and plugging the equation for R_{MR} into R_{S} therein, then I_{OUT} equals:

$${I}_{OUT} = {\frac{2}{{μ}_{n} {{C}_{ox} ( W \text{/} L )}_{n}} [ {μ}_{n} {{C}_{ox} ( W \text{/} L )}_{m} ( {V}_{G} - {V}_{thn} ) ]}^{2} {( 1 - \frac{1}{\sqrt{K}} )}^{2}$$

It is known that V_{OUT}=(I_{OUT})(R_{MS}). As such, V_{OUT} equals:

$$= {\frac{2}{{μ}_{n} {{C}_{ox} ( W / L )}_{n}} [ {μ}_{n} {{C}_{ox} ( W \text{/} L )}_{m} ( {V}_{G} - {V}_{thn} ) ]}^{2} {( 1 - \frac{1}{\sqrt{K}} )}^{2} \frac{1}{{μ}_{n} {{C}_{ox} ( W \text{/} L )}_{m} ( {V}_{G} - {V}_{thn} )}$$

By choosing the sizes of M₂ and M_{R} carefully, i.e., such that (W/L)ₘ=(W/L)ₙ, and knowing that V_{G} conforms to the following

$${V}_{G} = {V}_{thnD} + \sqrt{\frac{2 {I}_{D}}{{μ}_{n} {{C}_{ox} ( W \text{/} NL )}_{m}}}$$

then the equation reduces as follows and V_{OUT} equals:

$$= 2 ( {V}_{G} - {V}_{thn} ) {( 1 - \frac{1}{\sqrt{K}} )}^{2}$$

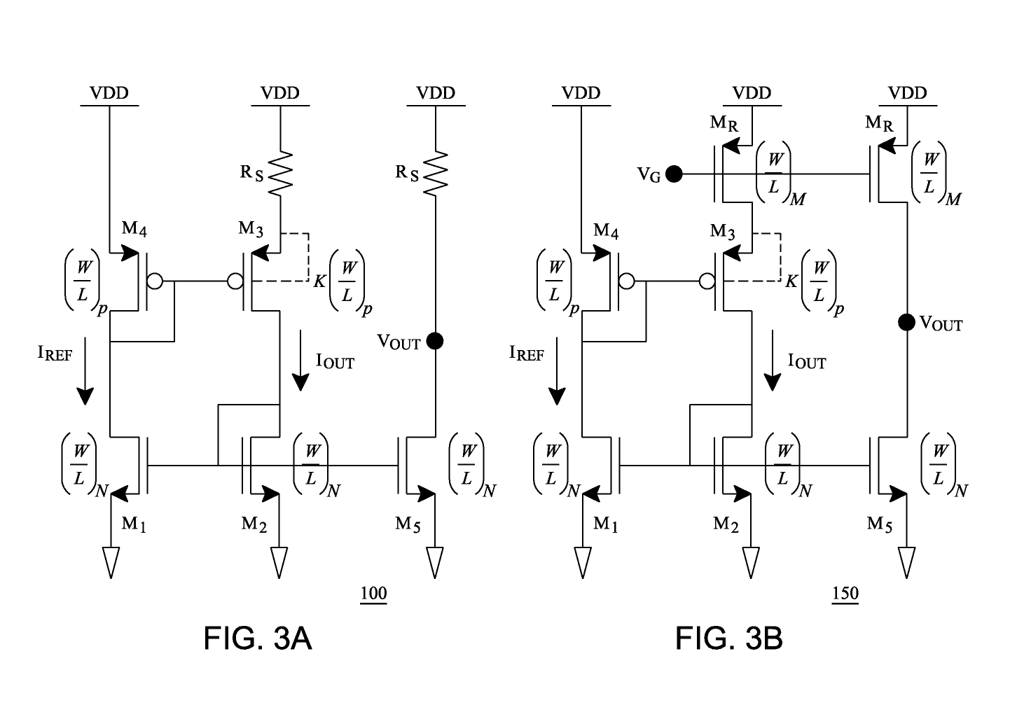

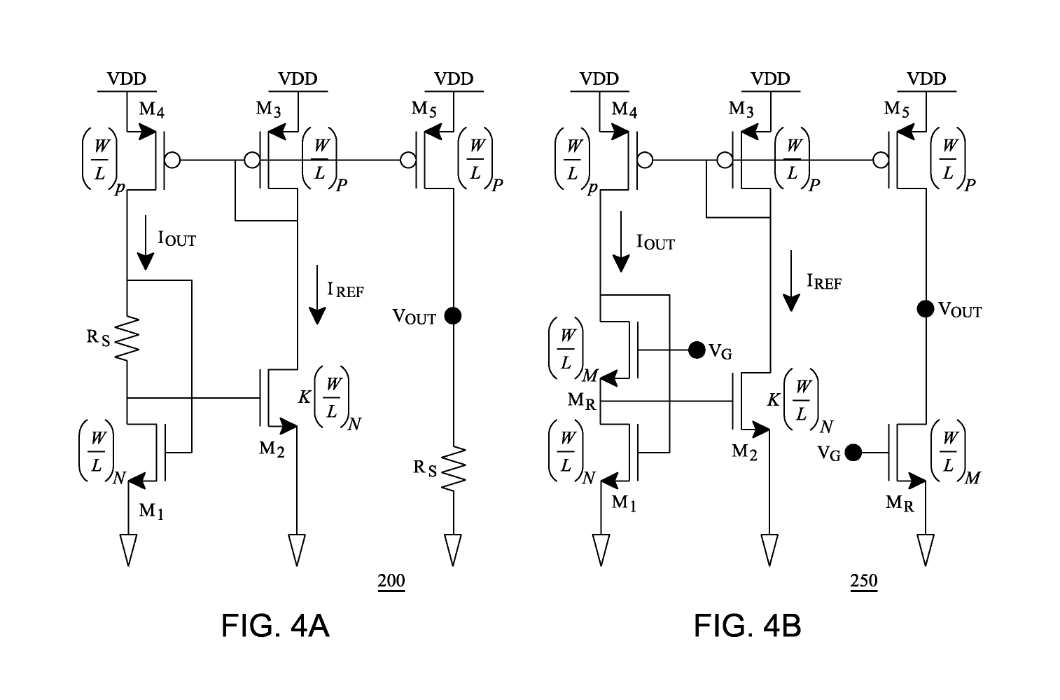

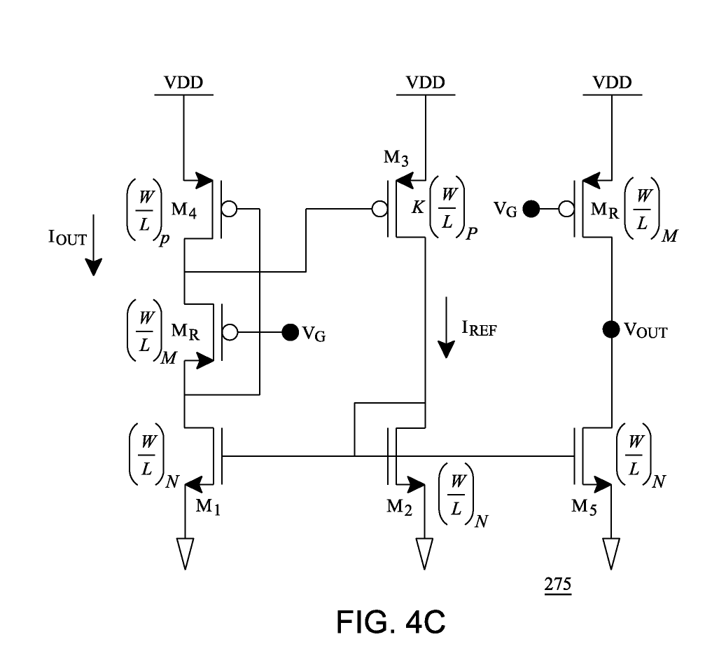

In other words, the output voltage is independent of the supply voltage. The gate voltage V_{G} can be generated from the gate of the diode connected transistor M_{D}. The transistor size ration K, is not dependent in any significant way on process and temperature variations. By replacing the on-die resistance R_{S} with a MOSFET, the bias current I_{OUT} and bias voltage V_{OUT} have been made independent of the supply voltage VDD and resistance variations. Further, this scheme can be adapted easily to other supply independent biasing circuits, as illustrated below in connection with FIGS. 3A, 3B, 4A and 4B.

As shown in FIG. 2, another stack of transistors M₆ and M_{D} can be used to provide the voltage V_{G} for properly biasing transistors M_{R} and M_{S} in the triode region. PMOS M6 mirrors the output current I_{OUT}. Transistor M_{D} is diode connected, with its drain terminal tied to its gate terminal. The transistors are coupled to one another at their respective drain terminals. It should be appreciated that the approach of FIG. 2 is not the only way to bias transistors M_{R} and M_{S} in the triode region. As long the transistors are biased such that V_{G}−Vₜₕ>V_{DS}, then both M_{R} and M_{S} will be in the triode region, which make M_{R} and M_{S} behave as resistors.

FIGS. 3A and 3B illustrate one embodiment of a supply independent biasing circuit 100 and an alternative embodiment of that circuit that replaces the die resistance R_{S} with a MOSFET as discussed above. In comparing the biasing circuit 100 of FIG. 3A to the biasing circuit 150 of FIG. 3B, it can be seen that the on-die resistance R_{S} have been replaced with MOSFETS M_{R}, which are in some embodiments equally sized for reasons discussed above.

The main difference between the biasing circuit 10 of FIG. 1 and biasing circuit 100 of FIG. 3A, and between the biasing circuit 50 of FIG. 2 and biasing circuit 150 of FIG. 3B, is the reversal of the polarity of the transistors. In FIGS. 1 and 2, PMOSs M3 and M4 are the current mirror for mirroring I_{REF} to I_{OUT}, but in FIGS. 3A and 3B NMOSs M1 and M2 are the current mirror for mirroring I_{REF} to I_{OUT}. Also, PMOS M5 (FIGS. 1 and 2) is changed to NMOS M5 (FIGS. 3A and 3B) for forming a third current mirror. Finally, NMOSs M_{R} and M_{S} of FIG. 2 become PMOSs M_{R} in FIG. 3B, with PMOSs M_{R} serving as the first and second resistive loads.

Though not shown in FIG. 3B, it should be understood that V_{G}, which is the biasing voltage for transistor M_{R}, can be generated in a manner similar to that shown in FIG. 2. For example, another stack of transistors can be provided including (i) an additional NMOS transistor forming another current mirror can be provided having the same size as transistors M1 and M2 and being commonly biased therewith, and (ii) a diode connected PMOS coupled between the VDD supply node and the drain of this additional NMOS transistor. The bias voltage V_{G} is provided by the voltage at the drain terminals of these transistors.

FIGS. 4A and 4B illustrate one embodiment of a supply independent biasing circuit 200 and an alternative embodiment of that circuit that replaces the on-die resistance R_{S} with a MOSFET properly biased at triode region as discussed above. In these embodiments, a resistance (either in the form of on-die resistance R_{S} (FIG. 4A) or transistor M_{R} (FIG. 4B)) is located between transistors M1 and M4, and the gate of transistor M2 is biased off of the drain node of transistor M1. When comparing the biasing circuit 200 of FIG. 4A to the biasing circuit 250 of FIG. 4B, it can be seen that the on-die resistances R_{S} have been replaced with MOSFETS M_{R}, which are in some embodiments sized the same.

Of course, it should be appreciated that the polarity of the transistors shown in FIG. 4B could be reversed in the manner described above. This embodiment of a biasing circuit 275 is illustrated in FIG. 4C.

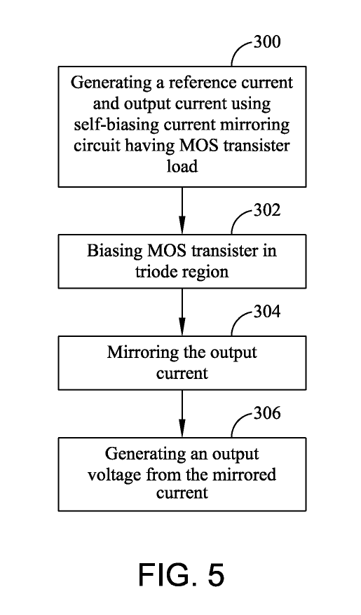

A method of supply independent biasing is shown in FIG. 5. At step 300, a reference current and an output current are generated using a self-biasing current mirroring circuit having a MOS transistor load as described above and illustrated in connection with FIG. 2, 3B, 4B or 4C, for example. At step 302, the MOS transistor is biased in the triode region. At step 304 the output current is mirrored. At step 306, an output voltage is generated from the mirrored current.

Per the foregoing description, in one embodiment a supply-independent biasing source includes an upper current mirror including first and second PMOS transistors and a lower current mirror coupled to the upper current mirror including first and second NMOS transistors. The first NMOS and first PMOS transistors have drain terminals coupled together and form a first stack of transistors and the second NMOS and second PMOS transistors have drain terminals coupled together and form a second stack of transistors. A first resistive load is connected to one of the first and second stacks, wherein the resistive load comprises a first MOSFET transistor biased at triode region.

In another embodiment of a supply-independent biasing source, the biasing source includes an upper current mirror including first and second PMOS transistors having source terminals coupled to a high supply node; a lower current mirror coupled to the upper current mirror including first and second NMOS transistors having source terminals coupled to a low supply node, wherein the first NMOS and first PMOS transistors have drain terminals coupled together and form a first stack of transistors and the second NMOS and second PMOS transistors have drain terminal coupled together and form a second stack of transistors; a first resistive load connected to one of the first and second stacks, wherein the first resistive load comprises a first MOSFET transistor biased at triode region; a third current mirror coupled to one of the upper and lower current mirrors for mirroring an output current therefrom; and a second resistive load coupled to the third current mirror for providing a supply-independent output voltage, wherein the second resistive load comprises a second MOSFET transistor biased at triode region, the first and second MOSFET transistors being of a same size.

In yet another embodiment o a supply-independent biasing source, the biasing-source includes an upper current mirror including first and second PMOS transistors having source terminals coupled to a high supply node; a lower current mirror coupled to the upper current mirror including first and second NMOS transistors having source terminals coupled to a low supply node, wherein the first NMOS and first PMOS transistors are coupled together at their drain terminals in a first stack of transistors and the second NMOS and second PMOS transistor are coupled together at their drain terminals in a second stack of transistors; a first resistive load connected to one of the first and second stacks, wherein the first resistive load comprises a first MOSFET transistor biased at triode region; a third current mirror coupled to one of the upper and lower current mirrors for mirroring an output current therefrom; a second resistive load coupled to the third current mirror for providing a supply-independent output voltage, wherein the second resistive load comprises a second MOSFET transistor, the second MOSFET transistor having a same size as the first MOSFET transistor; and means for biasing the first and second MOSFET transistors at triode region.

In a method of supply-independent biasing, the method includes the step of generating a reference current and an output current using a self-biasing current mirroring circuit. The self biasing current mirroring circuit includes an upper current mirror including first and second PMOS transistors; a lower current mirror coupled to the upper current mirror including first and second NMOS transistors, wherein the first NMOS and first PMOS transistors have drain terminals coupled together and form a first stack of transistors and the second NMOS and second PMOS transistors have drain terminals coupled together and form a second stack of transistors; and a first resistive load connected to one of the first and second stacks, wherein the resistive load comprises a first MOSFET transistor. The method further includes the step of biasing the first MOS transistor in the triode region.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention.

What is claimed is:

1. A supply-independent biasing source, comprising:
an upper current mirror including first and second PMOS transistors;
a lower current mirror coupled to the upper current mirror including first and second NMOS transistors, wherein the first NMOS and first PMOS transistors have drain terminals coupled together and form a first stack of transistors and the second NMOS and second PMOS transistors have drain terminals coupled together and form a second stack of transistors; and
a first resistive load connected to one of the first and second stacks, wherein the resistive load comprises a first MOSFET transistor biased at triode region.

2. The supply-independent biasing source of claim 1, wherein the first PMOS transistor provides a reference current and the first NMOS transistor mirrors the reference current to the second NMOS transistor, and the first NMOS transistor provides an output current and the first PMOS transistor mirrors the output current to the first PMOS transistor, wherein the first MOSFET transistor is a third NMOS transistor having a drain terminal coupled to a source terminal of the second NMOS transistor.

3. The supply-independent biasing source of claim 2, further comprising a third PMOS transistor having a gate terminal commonly biased with gate terminals of the first and second PMOS transistors, wherein the third PMOS transistor is coupled at a drain terminal to a second resistive load for providing a supply-independent output voltage, wherein the second resistive load comprises a second MOSFET transistor biased at triode region, and the second MOSFET transistor is a fourth NMOS transistor.

4. The supply-independent biasing source of claim 3, further comprising a fourth PMOS transistor having a gate terminal commonly biased with the gate terminals of the first, second and third PMOS transistors, wherein the fourth PMOS transistor is coupled at its drain terminal at a biasing node to a diode connected fifth NMOS transistor, wherein the biasing node is coupled to gate terminals of the third and fourth NMOS transistors for biasing the third and fourth NMOS transistor at triode region.

5. The supply-independent biasing source of claim 1, further comprising a third PMOS transistor having a gate terminal commonly biased with gate terminals of the first and second PMOS transistors, or a third NMOS transistor having a gate terminal commonly biased with gate terminals of the first and second NMOS transistors, wherein the third PMOS or NMOS transistor is coupled at a drain terminal to a second resistive load for providing a supply-independent output voltage, wherein the second resistive load comprises a second MOSFET transistor having a gate terminal commonly biased with a gate terminal of the first MOSFET transistor, and the first and second MOSFET transistors have the same size.

6. The supply-independent biasing source of claim 1, wherein the first NMOS provides a reference current and the first PMOS transistor mirrors the reference current to the second PMOS transistor, and the second PMOS transistor provides an output current and the second NMOS transistor mirrors the output current to the first NMOS transistor, wherein the first MOSFET transistor is a third PMOS transistor having a drain terminal coupled to a source terminal of the second PMOS transistor.

7. The supply-independent biasing source of claim 6, further comprising a third NMOS transistor having a gate terminal commonly biased with gate terminals of the first and second NMOS transistors, wherein the third NMOS transistor is coupled at a drain terminal to a second resistive load for providing a supply-independent output voltage, wherein the second resistive load comprises a second MOSFET transistor biased at triode region, and the second MOSFET transistor is a fourth PMOS transistor.

8. The supply-independent biasing source of claim 7, further comprising a fourth NMOS transistor having a gate terminal commonly biased with the gate terminals of the first, second and third NMOS transistors, wherein the fourth NMOS transistor is coupled at its drain terminal at a biasing node to a diode connected fifth PMOS transistor, wherein the biasing node is coupled to gate terminals of the third and fourth PMOS transistors for biasing the third and fourth PMOS transistor at triode region.

9. The supply-independent biasing source of claim 1, wherein the first MOSFET is connected between the drain terminals of the first NMOS and PMOS transistors.

10. The supply-independent biasing source of claim 9, wherein the first MOSFET transistor is a third NMOS transistor, a gate terminal of the first NMOS transistor is biased at the drain terminal of the first PMOS transistor and a gate terminal of second NMOS transistor is biased at the drain terminal of the first NMOS transistor.

11. The supply-independent biasing source of claim 9, wherein the first MOSFET transistor is a third PMOS transistor, a gate terminal of the first PMOS transistor is biased at the drain terminal of the first NMOS transistor and a gate terminal of the second PMOS transistor is biased at the drain terminal of the first PMOS transistor.

12. The supply-independent biasing source of claim 1, further comprising:
a third current mirror coupled to one of the upper and lower current mirrors for mirroring an output current therefrom; and
a second resistive load coupled to the third current mirror for providing a supply-independent output voltage, wherein the second resistive load comprises a second MOSFET transistor biased at triode region.

13. The supply-independent biasing source of claim 12, wherein the first and second MOSFET transistors being of a same size.

14. A supply-independent biasing source, comprising:
an upper current mirror including first and second PMOS transistors having source terminals coupled to a high supply node;
a lower current mirror coupled to the upper current mirror including first and second NMOS transistors having source terminals coupled to a low supply node, wherein the first NMOS and first PMOS transistors have drain terminals coupled together and form a first stack of transistors and the second NMOS and second PMOS transistors have drain terminal coupled together and form a second stack of transistors;
a first resistive load connected to one of the first and second stacks, wherein the first resistive load comprises a first MOSFET transistor biased at triode region;
a third current mirror coupled to one of the upper and lower current mirrors for mirroring an output current therefrom; and
a second resistive load coupled to the third current mirror for providing a supply-independent output voltage, wherein the second resistive load comprises a second MOSFET transistor biased at triode region, the first and second MOSFET transistors being of a same size.

15. The supply-independent biasing source of claim 14,
wherein the third current mirror includes a third PMOS transistor having a gate terminal commonly biased with gate terminals of the first and second PMOS transistors, and the first and second MOSFET transistors are third and fourth NMOS transistors, respectively, or
wherein the third current mirror includes a third NMOS transistor having a gate terminal commonly biased with gate terminals of the first and second NMOS transistors, and the first and second MOSFET transistors are third and fourth PMOS transistors, respectively.

16. The supply-independent biasing source of claim 14, wherein the first MOSFET is connected between the drain terminals of the first NMOS and PMOS transistors.

17. The supply-independent biasing source of claim 16, wherein the first MOSFET transistor is a third NMOS transistor, a gate terminal of the first NMOS transistor is biased at the drain terminal of the first PMOS transistor and a gate terminal of second NMOS transistor is biased at the drain terminal of the first NMOS transistor.

18. The supply-independent biasing source of claim 16, wherein the first MOSFET transistor is a third PMOS transistor, a gate terminal of the first PMOS transistor is biased at the drain terminal of the first NMOS transistor and a gate terminal of the second PMOS transistor is biased at the drain terminal of the first PMOS transistor.

19. A method of supply-independent biasing, comprising the steps of:
generating a reference current and an output current using a self-biasing current mirroring circuit, the self biasing current mirroring circuit comprising:
an upper current mirror including first and second PMOS transistors;
a lower current mirror coupled to the upper current mirror including first and second NMOS transistors, wherein the first NMOS and first PMOS transistors have drain terminals coupled together and form a first stack of transistors and the second NMOS and second PMOS transistors have drain terminals coupled together and form a second stack of transistors; and
a first resistive load connected to one of the first and second stacks, wherein the resistive load comprises a first MOSFET transistor; and
biasing the first MOS transistor in the triode region.

20. The method of claim 19,
wherein one of the first and second stacks of transistors provides the output current and the other of the first and second stacks of transistors provides the reference current, and the first MOSFET transistor is coupled to the one of the first and second stacks of transistors,
the method further comprising the step of mirroring the output current and generating an output voltage from the mirrored current.
